(19) United States
(12) Patent Application Publication
(10) Pub. No.: US 2020/0249567 A1
(43) Pub. Date: Aug. 6, 2020

(54) IMPRINT TEMPLATES, METHOD FOR MANUFACTURING IMPRINT TEMPLATES, AND METHOD FOR MANUFACTURING SEMICONDUCTOR DEVICES

(71) Applicant: TOSHIBA MEMORY CORPORATION, Tokyo (JP)

(72) Inventors: Kazuya FUKUHARA, Suginami Tokyo (JP); Shingo KANAMITSU, Kawasaki Kanagawa (JP)

(21) Appl. No.: 16/551,239

(22) Filed: Aug. 26, 2019

(30) Foreign Application Priority Data
Feb. 1, 2019 (JP) 2019-016866

(51) Int. Cl. G03F 7/00; G03F 1/38; H01L 21/033; B29C 59/02; B29C 35/08

(52) U.S. Cl. CPC G03F 7/0002; G03F 1/38; B29C 2035/0827; B29C 59/02; B29C 35/0805; H01L 21/0337

(57) ABSTRACT

According to one embodiment, an original plate such as an imprint template or the like, comprises a substrate having a first surface. A pattern region is on the first surface. An impurity layer is within the substrate in a plane parallel to the first surface. The pattern region is within an outer perimeter of the impurity layer when viewed from a direction orthogonal to the first surface.

### CROSS-REFERENCE TO RELATED APPLICATION

This application is based upon and claims the benefit of priority from Japanese Patent Application No. 2019-016866, filed Feb. 1, 2019, the entire contents of which are incorporated herein by reference.

### FIELD

Embodiments described herein relate generally to imprint templates, a method for manufacturing imprint templates, and a method for manufacturing semiconductor devices.

### BACKGROUND

Imprint methods are known as techniques for fine patterning in the manufacture of semiconductor devices. With imprint methods, a pattern on an imprint template is transferred to a substrate. In general, there is some distortion between the pattern formed on the substrate and the original template pattern. When the template and the substrate o are superimposed, positional displacements and pattern misalignments may occur. A high-order correction technology can be used during the imprint process. For example, a substrate to be imprinted/patterned is irradiated with light that is transmitted through the template during the imprint process and thus may be deformed by thermal expansion and such deformation may need to be accounted and/or compensated for in template-substrate pattern alignment.

In some examples, the template used in the imprinting process is itself a replica of an original mold or platen, referred to as a master or a master template. Such replicas (imprint templates) may be formed from a master using an imprinting process similar to that used in manufacturing a semiconductor device. As such, the pattern on the replica may likewise be formed with positional displacement(s) relative to the master's pattern and a high-order distortion correction technique may thus be required in making the replica. However, since the master and the replica are often made of the same type of material, it may be difficult to apply high-order correction techniques in the replica fabrication process.

### DESCRIPTION OF THE DRAWINGS

FIG. 1 is a cross-sectional view of a master template according to a first embodiment.

FIGS. 2A to 2D are top views illustrating aspects of the master template according to a first embodiment.

FIG. 3 is a flow chart illustrating aspects of a method for manufacturing a master template according to a first embodiment.

FIGS. 4A to 4D are cross-sectional views schematically illustrating aspects of a method for manufacturing a master template according to a first embodiment.

FIG. 5 is a flow chart illustrating aspects of a method for manufacturing a replica template according to a first embodiment.

FIGS. 6A to 6H are cross-sectional views illustrating aspects of a method for manufacturing a replica template according to a first embodiment.

FIG. 7 is a cross-sectional view illustrating a configuration of a replica template according to a second embodiment.

FIG. 8 is a flow chart illustrating aspects of a method for manufacturing a semiconductor device using a replica template according to a second embodiment.

FIGS. 9A to 9F are cross-sectional views illustrating aspects of a method for manufacturing a semiconductor device using a replica template according to a second embodiment.

FIG. 10 is a top view illustrating a replica template according to a second embodiment.

### DETAILED DESCRIPTION

In general, according to one embodiment, a template or a template master includes a substrate having a pattern provided on a first surface and an impurity layer in the substrate. The impurity layer is disposed to include a pattern region in which the pattern is provided. The impurity layer is in a plane parallel to the first surface. The pattern region is within an outer perimeter of the impurity layer when viewed from a direction orthogonal to the first surface.

Hereinafter, an original plate, a method for manufacturing the original plate, and a method for manufacturing a semiconductor device according to an embodiment will be described with reference to the drawings. The present disclosure is not limited to these example embodiments. Further, the cross-sectional views of the original plate and the semiconductor device used in the following embodiment are schematic, and, for example, a relationship between the thickness and width of the layers, and the ratio of the thickness of each layer may be different from actual ones.

### First Embodiment

In a first embodiment, a master template capable of correcting for high-order distortion at the time of pattern transfer to a replica template and a method for manufacturing the same will be described. That is, in this example, the “original plate” is a master template used to fabricate replica templates.

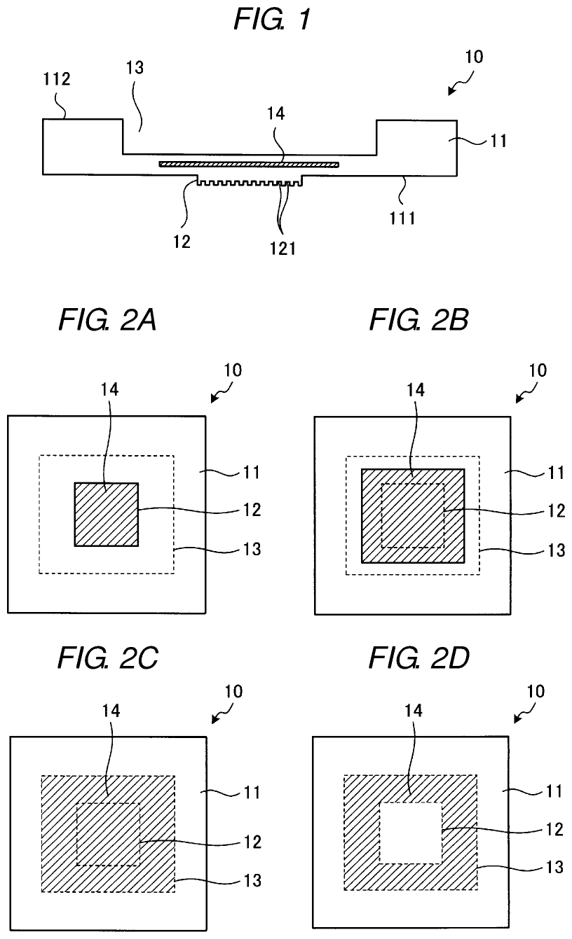

FIG. 1 is a cross-sectional view illustrating a configuration of a master template according to a first embodiment. FIGS. 2A to 2D are top views illustrating configurations of the master template according to the first embodiment. FIGS. 2A to 2D are top views in which hatching is used to indicate presence of an impurity layer 14.

A master template 10 includes a pedestal 12 on which an pattern 121 is provided. The pedestal 12 is on a first surface 111 of a template substrate 11. A recess 13 is on a second surface 112, which is opposite to the first surface 111. The pedestal 12 is provided at substantially the center of the first surface 111 and is protruded above the peripheral edge portion. The pattern 121 is an arbitrary pattern to be brought into contact with a resist on a processing target object during an imprint process. The recess 13 includes a region corresponding to the pedestal 12. The thickness of the template substrate 11 in the region where the recess 13 is provided is a thickness that allows the pattern 121 to be deformed by thermal expansion. The template substrate 11 may be made of a material that transmits ultraviolet light. The template substrate 11 is made of, for example, quartz.

An impurity layer 14 is provided in the template substrate 11. The impurity layer 14 is a layer formed by implanting an impurity into the template substrate 11 at a predetermined concentration. The impurity is capable of absorbing visible to the infrared light, but transmitting ultraviolet light. The impurity includes at least one element selected from a group of elements including C, Mg, Al, P, Ca, Ti, Cr, Fe, Co, Ni, Cu, Zn, Ga, Ge, Mo, Ag, Sn, Sb, Ta, W, Os, Pt, Au, and Pb. The impurity element is implanted, for example, into the template substrate 11 at a dose of about 10¹⁶/cm².

The impurity layer 14 is provided so as to deform to adjust the position of the pattern 121 of the master template 10 when fabricating the replica template in accordance with a positional displacement of a lower layer pattern formed on the processing target object. The deformation of the pattern 121 is achieved by the impurity layer 14 absorbing electromagnetic waves in the visible to the infrared light region that are specifically applied based on the positional displacement amount of the lower layer pattern already formed on the processing target object.

The impurity layer 14 may be provided in any position in plan view. Preferably, as illustrated in FIGS. 2A to 2D, the impurity layer 14 is provided in a region in plan view where the template substrate 11 has a small thickness (e.g., portion with the recess 13). FIG. 2A illustrates a case where the region of the impurity layer 14 has substantially the same size as the region of the pedestal 12 and these regions are overlapped. FIG. 2B illustrates a case where the region of the impurity layer 14 is larger than the region of the pedestal 12, but smaller than the region of the recess 13. FIG. 2C illustrates a case where the region of the impurity layer 14 has substantially the same size as the region of the recess 13 and these regions are overlapped. FIG. 2D illustrates a case where the region of the impurity layer 14 is an annular region between the edge of the pedestal 12 and the edge of the region of the recess 13. That is, the impurity layer 14 is disposed to surround the region of the pedestal 12.

When visible light and/or infrared light is applied to the portion of impurity layer 14 present within the region of the pedestal 12, the irradiated portion of the impurity layer 14 is heated and thus thermally expands, and a force acts such that the region of the pedestal 12 also expands. However, when visible and/or infrared light is applied to the portion of the impurity layer 14 outside the region of the pedestal 12, this irradiated portion of the impurity layer 14 is heated and thus thermally expands, and a force acts such that the region of the pedestal 12 is compressed. Since the force applied to the region of the pedestal 12 differs depending on the position of the impurity layer 14, it is possible to perform the high-order distortion correction.

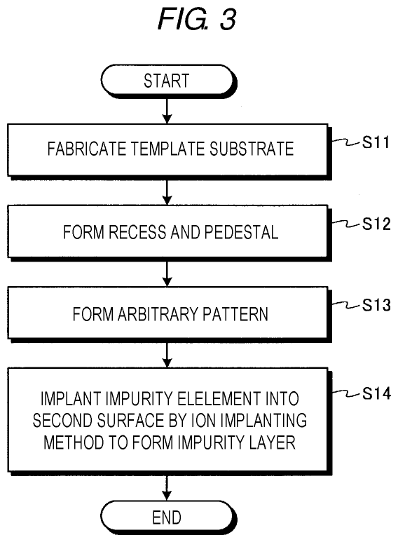

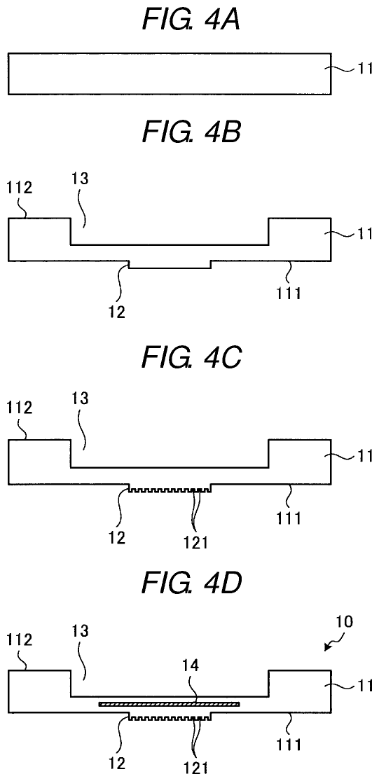

Next, a method for manufacturing the master template 10 will be described. FIG. 3 is a flow chart illustrating a method for manufacturing the master template according to the first embodiment. FIGS. 4A to 4D are cross-sectional views schematically illustrating a method for manufacturing the master template according to the first embodiment.

First, a template substrate 11 having a flat plate shape is fabricated (step S11, FIG. 4A). A quartz substrate having a flat plate shape may be adopted as the template substrate 11. Next, the recess 13 is formed by performing a counterbore process on the second surface 112 of the template substrate 11, and the pedestal 12 is formed on the first surface 111 by, for example, a chemical mechanical polishing (CMP) method or an etching method (step S12, FIG. 4B).

Thereafter, a resist is applied onto the pedestal 12, and the resist is patterned using an electron beam drawing technique followed by a development technique to form a resist pattern. Thereafter, the template substrate 11 is processed by anisotropic etching, such as a reactive ion etching (RIE) method, using the resist pattern as a mask. As a result, the pattern 121 is formed on the surface of the pedestal 12 (step S13, FIG. 4C). A hard mask film may be provided between the resist pattern and the pedestal 12.

After stripping the resist pattern, the impurity is implanted through the second surface 112 of the template substrate 11 according to an ion implanting method and the impurity layer 14 is formed (step S14). At this time, the ion implanting dose amount per unit area is, for example, about 10¹⁶/cm². Further, the impurity element is ion-implanted such that the impurity layer 14 is formed at a position as illustrated in any one of FIGS. 2A to 2D. As described above, the master template 10 is fabricated.

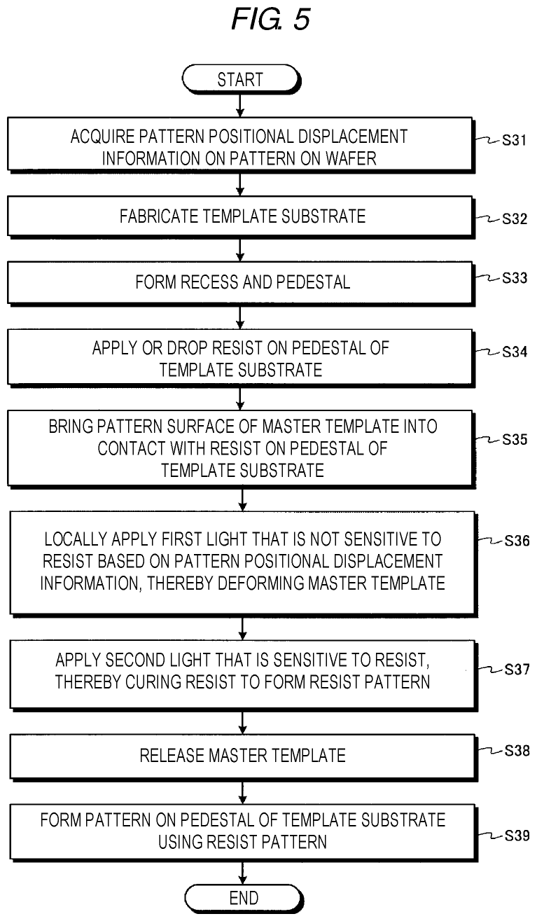

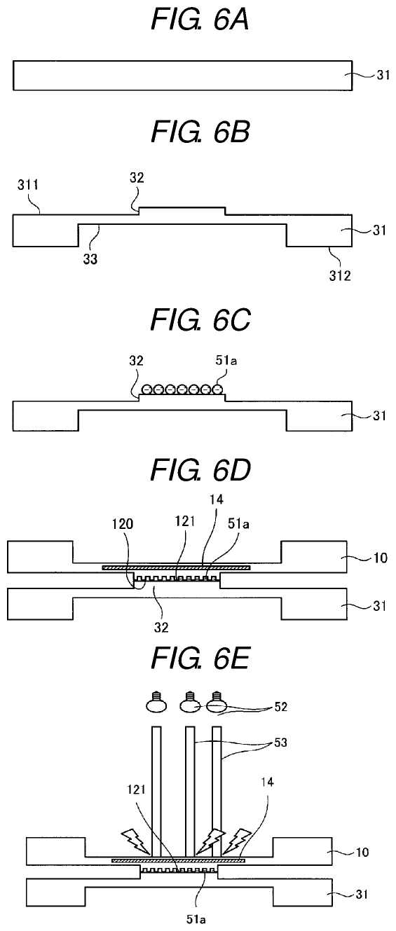

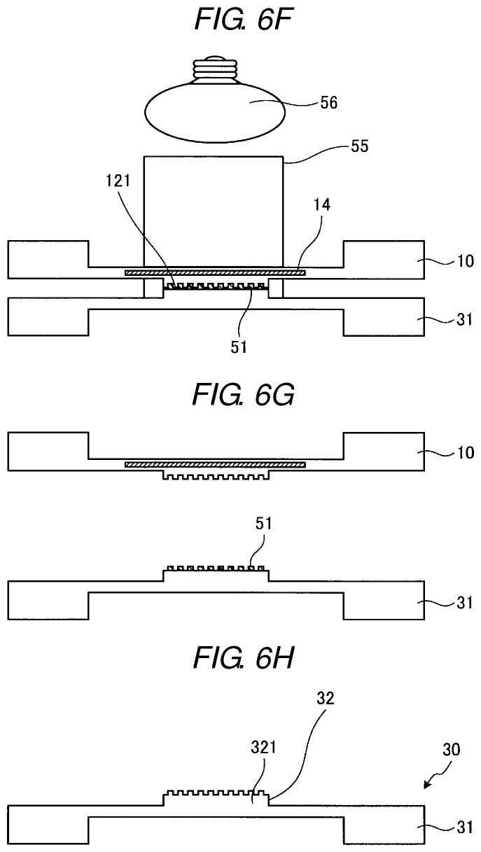

Next, a method for manufacturing the replica template using the master template 10 will be described. FIG. 5 is a flow chart illustrating a method for manufacturing the replica template according to the first embodiment. FIGS. 6A to 6H are cross-sectional views schematically illustrating a method for manufacturing the replica template according to the first embodiment.

First, pattern positional displacement information on the pattern of the lower layer formed on a wafer, which is a processing target object, is acquired (step S31). The positional displacement information is information that indicates a degree of displacement of the actual pattern position formed on the wafer from the ideal pattern position on the wafer. The positional displacement information is acquired by, for example, detecting a position of an alignment mark or an array of marks or the like on the wafer using, for example, a laser interferometer.

Next, a template substrate 31, which will be serving as the replica template, is fabricated (step S32, FIG. 6A). A quartz substrate having the flat plate shape may be used as the template substrate 31. Next, the recess 33 is formed by performing a counterbore process on the second surface 312 of the template substrate 31. The pedestal 32 is formed on the first surface 311 by, for example, a CMP method or an etching method (step S33, FIG. 6B).

Thereafter, a resist 51a is applied or dispensed on the pedestal 32 (step S34, FIG. 6C). The resist 51a is applied by, for example, a method such as a slit coating method, or is dispensed by a method such as an ink jetting method. An ultraviolet curing resin that is not sensitive to visible light and/or infrared light region is used as the resist 51a.

Next, a pattern surface 120 of the master template 10 is brought into contact with the resist 51a on the pedestal 32 of a replica template 30 (step S35, FIG. 6D). As a result, the pattern recesses provided in the pattern surface 120 of the master template 10 are filled with the resist 51a.

A first light 53, to which the resist 51a is not sensitive, is locally applied to the impurity layer 14 of the master template 10 based on the pattern positional displacement information (step S36, FIG. 6E). The first light 53 is visible and/or infrared light and is emitted froma light source 52. The first light 53 is applied to the impurity layer 14 such that the same or otherwise compensating displacement from the ideal position that occurred on the previous patterning of the wafer occurs in the pattern 121 of the master template 10. The irradiation time or the intensity of the first light 53 may be changed according to the positional displacement amount.

The impurity layer 14 at the position irradiated with the first light 53 absorbs the first light 53 and is thermally expanded. Due to the thermal expansion, the master template 10 is deformed, and consequently, the pattern 121 is also deformed. The deformation of the pattern 121 is provided to be substantially the same as the positional displacement occurring on the wafer.

Thereafter, second light 55, to which the resist 51a is sensitive, is applied to the resist 51a. The second light 55 is ultraviolet light and is emitted from a light source 56. When irradiated with the second light 55, the resist 51a is cured, and a resist pattern 51 is formed (step S37, FIG. 6F).

After the resist pattern 51 is formed, the master template 10 is separated from the resist pattern 51 (step S38, FIG. 6G). Next, the template substrate 31 is etched using anisotropic etching technology such as the RIE method, using the resist pattern 51 as a mask. As a result, a pattern having a positional displacement corresponding to the positional displacement of the pattern already on the wafer is transferred to the pedestal 32 of the template substrate 31 (step S39). Thereafter, the resist pattern 51 is stripped or asked off, and an inspection or the like is performed, and the correction of the pattern or the like is performed, and whereby the replica template 30 is obtained.

The case where the master template 10 includes the pedestal 12 having the pattern 121 on the first surface 111 and the recess on the second surface 112 has been described as one, non-limiting example. For example, the impurity layer 14 may be provided in a template substrate having a thin flat plate shape that has been provided with the pedestal 12 having the pattern on the first surface 111. That is, the thickness of the entirety of the template substrate may be substantially the same as, for example, the thickness at the position of the recess 13 in the template substrate 11 described in FIG. 1.

In the first embodiment, the master template 10 includes the impurity layer 14 in the template substrate 11, which absorbs the first light 53 from the visible light region to the infrared light region, and transmits the second light 55 in the ultraviolet light region. As a result, in the fabrication of the replica template 30, the first light 53 may be applied to a desired position to deform the pattern 121. As a result, it is possible to obtain a replica template 30 provided with a pattern in which high-order distortion has been controlled or compensated.

Further, by using the master template 10 for fabricating the replica template 30, it is possible to inexpensively fabricate replica templates 30 having the necessary positional displacement corrections according to positional displacements occurring on a wafer which is a transfer target of the pattern on the replica templates 30. In addition, when the amount and type of the positional displacement on the wafer is fixed (constant), it is possible to inexpensively manufacture a semiconductor device by using such a replica template 30.

### Second Embodiment

In the first embodiment, the case where the impurity layer is provided in the master template was described. In a second embodiment, a case where an impurity layer is provided in a replica template will be described. That is, a case in which an original plate is a replica template will be described.

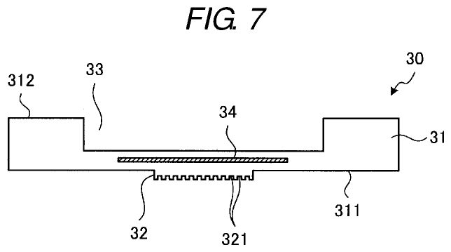

FIG. 7 is a cross-sectional view illustrating a configuration of a replica template according to the second embodiment. A replica template 30 includes the pedestal 32, on which a pattern 321 is provided. The pedestal 32 is on a first surface 311 of the template substrate 31. The recess 33 is on a second surface 312, which is opposite to the first surface 311. The pedestal 32 is provided at substantially the center of the first surface 311 and is protruded from the peripheral edge portion of the first surface 311. The pattern 321 is an arbitrary pattern that is brought into contact with a resist on a processing target object during the imprint process. The recess 33 is provided to include the region corresponding to the pedestal 32. The thickness of the template substrate 31 in the region in which the recess 33 is provided allows the pattern 321 to be deformed by thermal expansion. The template substrate 31 may be made of a material that transmits ultraviolet light. The template substrate 31 is made of, for example, quartz.

An impurity layer 34 is provided in the template substrate 31. The impurity layer 34 is a layer formed by implanting an impurity into the template substrate 31 at a predetermined concentration. The impurity is an capable of absorbing visible light and/or infrared light, and transmitting ultraviolet light. In this example, the impurity includes at least one element selected from a group of elements including C, Mg, Al, P, Ca, Ti, Cr, Fe, Co, Ni, Cu, Zn, Ga, Ge, Mo, Ag, Sn, Sb, Ta, W, Os, Pt, Au, and Pb. The impurity is implanted, for example, into the template substrate 31 with a dose of about 10¹⁶/cm² (atoms/cm²).

The impurity layer 34 is provided to permit deformation of the pattern 321 in accordance with the positional displacement of a pattern already formed on a processing target wafer, similar to the example of the impurity layer 14 of the master template 10. Here, the position of the impurity layer 34 in plan view cane be the same as that of any of the examples illustrated in FIGS. 2A to 2D.

Here, the replica template 30 can be obtained by ion-implanting the above impurity element at a predetermined concentration using ion implanting from the recess 33 side of the template substrate 31, for example, after the processing of FIG. 6H.

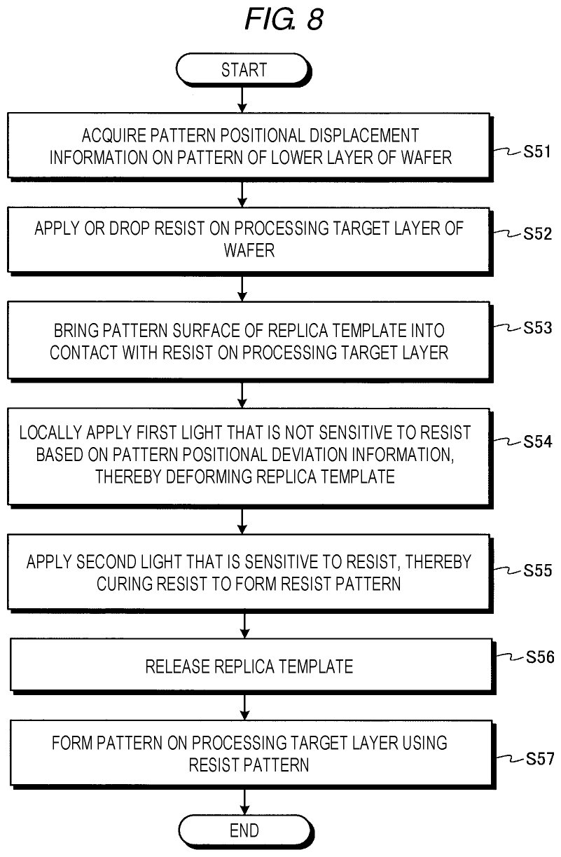

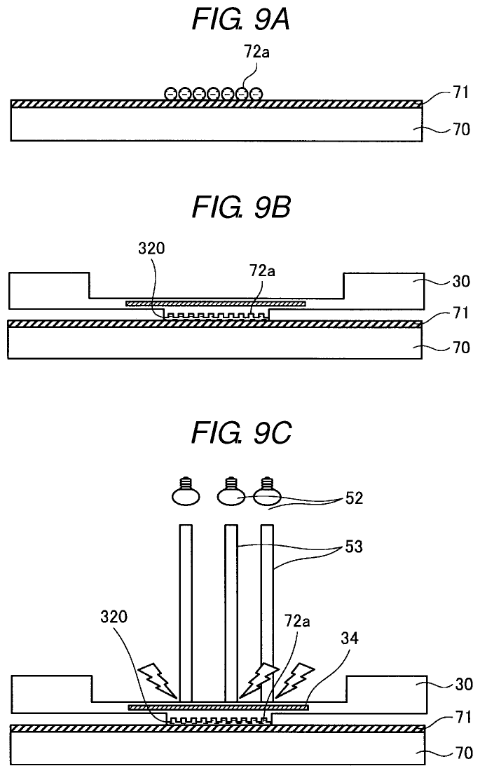

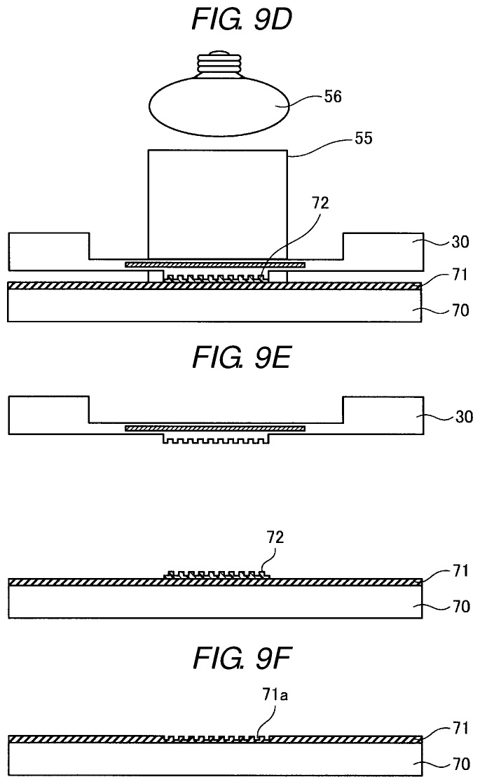

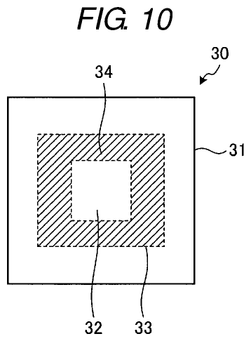

Next, a method for manufacturing a semiconductor device using a replica template 30 will be described. FIG. 8 is a flow chart illustrating a method for manufacturing the semiconductor device using a replica template according to the second embodiment. FIGS. 9A to 9F are cross-sectional views schematically illustrating a method for manufacturing a semiconductor device using a replica template according to the second embodiment.

First, pattern positional displacement information for the pattern of the lower layer already formed on a wafer 70 is acquired (step S51). The positional displacement information is substantially the same as that described in the context of the first embodiment. Next, a processing target layer 71 which is an upper layer of the wafer 70 is formed, and a resist 72a is applied or dispensed on the processing target layer 71 again (step S52, FIG. 9A) . The resist 72a is applied by, for example, a method such as a slit coating method, or is dispensed by a method such as an ink jetting method. A material such as an ultraviolet curing resin that is not sensitive to visible light and infrared light is used as the resist 72a.

Next, a pattern surface 320 of the replica template 30 is brought into contact with the resist 72a on the wafer 70 (step S53, FIG. 9B) . As a result, the pattern recesses provided in the pattern surface 320 of the replica template 30 are filled with the resist 72a.

Further, at this time, a first light 53, to which the resist 72a is not sensitive, is locally supplied (from the light source 52) to the impurity layer 34 of the replica template 30 based on the previously obtained pattern positional displacement information (step S54, FIG. 9C) . The first light 53 is electromagnetic radiation from the visible light region to the infrared light region. Further, the first light 53 is applied to the impurity layer 34 so that the same or otherwise compensating displacement from the ideal position occurring on the wafer 70 occurs in the pattern 321 of the replica template 30. The irradiation time or the intensity of the first light 53 may be changed according to the necessary positional displacement amount. As a result, the impurity layer 34 is thermally expanded, and the pattern 321 of the replica template 30 is deformed. The deformation of the pattern 321 is substantially the same as the positional displacement occurring on the pattern of the lower layer.

Thereafter, the second light 55 is applied from the light source 56 to the resist 72a. The second light 55 is ultraviolet light (electromagnetic radiation). When irradiated with the second light 55, the resist 72a is cured, and a resist pattern 72 is formed (step S55, FIG. 9D).

After the resist pattern 72 is formed, the replica template 30 is separated from the resist pattern 72 (step S56, FIG. 9E). Next, the processing target layer 71 is etched using anisotropic etching technology such as an RIE method, using the resist pattern 72 as a mask. As a result, a pattern 71a having a positional displacement corresponding to the positional displacement of the pattern on the lower layer of the wafer 70 is transferred to the processing target layer 71 (step S57, FIG. 9F). Thereafter, the semiconductor device is obtained by removing the resist pattern 72.

When the first light 53 is applied as shown in FIG. 9C, a portion of the first light 53 passes through the replica template 30 and reaches the wafer 70. As a result, the first light is absorbed at the wafer 70, and the pattern of the lower layer may also be further deformed by heating.

FIG. 10 is a top view illustrating a configuration of the replica template according to the second embodiment. The first light 53 may be applied only outside of the region (the pedestal 32 region) being imprinted on the wafer 70. As a result, the first light 53 is not applied to the region of the processing target layer 71 being patterned, and additional deformation of the pattern of the lower layer can be limited.

When the pattern of the lower layer would be expected to be deformed by application of the first light 53 to the wafer 70, then the deformation of the pattern of the replica template 30 by the first light 53 can be performed by only applying light to the impurity payer 14 outside the region where the pattern is being formed. That is, the resist pattern 72 may be formed by deforming both the pattern of the lower layer of the wafer 70 and the pattern 321 of the replica template 30.

The case where the replica template 30 includes the pedestal 32 having the pattern 321 on the first surface 311 and the recess 33 on the second surface 312 has been described as a non-limiting example. For example, the impurity layer may be provided in a template substrate having a thin flat plate shape provided with the pedestal 32 having the pattern 321 on the first surface 311. The thickness of the entire template substrate may be substantially constant at a thickness that matches the template substrate thickness at the position of the recess 33 in the template substrate 31 described in conjunction with FIG. 7.

In the second embodiment, the replica template 30 includes the impurity layer 34 in the template substrate 31. The impurity layer 34 absorbs the first light 53 in visible light region and/or the infrared light region, and transmits the second light 55 in the ultraviolet light region. As a result, in the formation of the pattern on the wafer 70, the first light 53 may be applied to a desired position for deforming the pattern 321 of the template substrate 31. As a result, it is possible to obtain a semiconductor device with the pattern 71a in which high-order distortion has been controlled.

Further, by using the replica template 30 for manufacturing the semiconductor device, it is possible to form the pattern 71a according to the distortion of the pattern of the lower layer of the wafer 70, even in a case where distortion of the pattern of the lower layer may be different for each wafer 70 processed.

In the above descriptions, an imprint template, also referred to as an imprint mold, is used as an example for an original plate, but the original plate may instead be a photomask in other examples.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A template, comprising:
a substrate having a first surface;
a pattern region on the first surface; and
an impurity layer within the substrate in a plane parallel to the first surface, the pattern region being within an outer perimeter of the impurity layer when viewed from a direction orthogonal to the first surface.

2. The template according to claim 1, wherein the impurity layer absorbs visible or infrared light, and transmits ultraviolet light.

3. The template according to claim 1, wherein the impurity layer includes as a dopant at least one element selected from a group of C, Mg, Al, P, Ca, Ti, Cr, Fe, Co, Ni, Cu, Zn, Ga, Ge, Mo, Ag, Sn, Sb, Ta, W, Os, Pt, Au, and Pb.

4. The template according to claim 1, wherein the pattern region is on a pedestal formed on the first surface of the substrate .

5. The template according to claim 1, wherein
the substrate includes a recess on a second surface opposite to the first surface, and
the recess is wider than the pattern region in a direction parallel to the first and surfaces.

6. The template according to claim 1, wherein the substrate is a quartz plate.

7. A method for manufacturing a template, comprising:
placing a resist material on a first surface of a first substrate;
contacting the resist material with a pattern region on a first surface of a second substrate;
applying a first light to the second substrate while in contact with the resist, the second substrate having an impurity layer within the second substrate in a plane parallel to the first surface, the pattern region begin within an outer perimeter of the impurity layer when viewed from a direction orthogonal to the first surface, the first light comprising a first wavelength light that is absorbed by impurity layer;
curing the resist in contact with the pattern region with a second light comprising a second wavelength different than the first wavelength; and
releasing the second substrate from the first substrate after the curing of the resist.

8. The method according to claim 7, further comprising:
processing the first substrate using the cured resist as a mask.

9. The method according to claim 7, wherein the impurity layer absorbs visible light or infrared light, and transmits ultraviolet light.

10. The method according to claim 7, wherein the impurity layer completely overlaps the pattern region when viewed in the direction orthogonal to the first surface.

11. The method according claim 7, wherein the impurity layer as annular shape and does not overlap the pattern region when viewed in the direction orthogonal to the first surface.

12. The method according to any claim 7, wherein the first light is applied based on positional displacement information indicating a first pattern displacement for a pattern formed on a processing target object.

13. The method according to claim 12, wherein the first light is selectively applied to the second substrate such that the first substrate is patterned with a second positional displacement corresponding to the first positional displacement.

14. The method according to claim 7, wherein the first substrate and the second substrate are each made of a material that transmits both the first light and the second light.

15. A method for manufacturing a semiconductor device, comprising:
providing a resist on a target object;
bringing a patterned surface of a template into contact with the resist, the template including an impurity layer therein;
applying first light to the impurity layer of the template;
applying second light to the resist to cure the resist;
releasing the template from the target object; and
processing the target object using the cured resist as a mask.

16. The method according to claim 15, wherein the impurity layer contains an impurity element that absorbs the first light, and the first light is in a wavelength range of visible light to infrared light, and transmits the second light, which is in an ultraviolet range.
